(19) United States
(12) Patent Application Publication
(10) Pub. No.: US 2012/0181653 A1
(43) Pub. Date: Jul. 19, 2012

(54) SEMICONDUCTOR PN JUNCTION STRUCTURE AND MANUFACTURING METHOD THEREOF

(75) Inventors: TSUNG-YI HUANG, Zhubei City (TW); Hung-Der Su, Pingzhen City (TW); Kuo-Cheng Chang, Bali Township (TW); Chun-Yi Hung, Dali City (TW); Kuo-Hsuan Lo, Taoyuan City (TW); Jeng Gong, Taichung City (TW)

(73) Assignee: Richtek Technology Corporation, R.O.C.

(21) Appl. No.: 13/005,754

(22) Filed: Jan. 13, 2011

(51) Int. Cl. H01L 29/06; H01L 21/04

(52) U.S. Cl. 257/487; 438/510; 257/E29.005; 257/E21.04

(57) ABSTRACT

The present invention discloses a semiconductor PN junction structure and a manufacturing method thereof. From top view, the PN junction includes a staggered comb-teeth structure. The PN junction forms a depletion region with enhanced breakdown voltage, hence broadening the applications of a semiconductor device having such PN junction.

### BACKGROUND OF THE INVENTION

1. Field of Invention

The present invention relates to a semiconductor PN junction structure and a manufacturing method thereof, in particular to such structure and method that enhances the breakdown voltage of a semiconductor device.

2. Description of Related Art

FIGS. 1A and 1B show, by top view and cross-section view respectively, a prior art semiconductor PN junction structure. As shown in the top view and cross-section view, a P-type region 11 and an N-type region 12 interface with each other to form a PN junction 13. From top view, the interface of the PN junction 13 is approximately a straight line. When no bias voltage, or when a reverse bias voltage is exerted on the P-type region 11 and the N-type region 12 (that is, a positive voltage is exerted on the N-type region 12 and a negative voltage is exerted on the P-type region 11), as shown in FIG. 1C, a depletion region 14 is formed around the PN junction 13. The width and the electric field of the depletion region 14 are related to the bias voltage, and the species and concentration of P-type impurities and N-type impurities in the P-type region 11 and the N-type region 12. When no bias voltage is exerted on the PN junction 13, the strength and distribution of the electric field are shown as FIG. 1D, while the width of the depletion region 14 is d1 as shown in FIG. 1C. In FIG. 1D, the horizontal axis represents the position x; the vertical axis represents the electric field E; and the bold line 15 indicates the strength distribution of the electric field.

The above-mentioned PN junction is widely applied in various semiconductor devices but it has a limit in its breakdown voltage. As the technology trend requires lower operation voltage of a semiconductor device and lower thermal budget in a semiconductor manufacturing process, the concentrations of the P-type and N-type well regions increase, while the breakdown voltage of the PN junction decreases. Hence, if it is desired to increase the breakdown voltage of the PN junction without changing the concentration of the impurities, a new PN junction structure is required such that a semiconductor device having such new PN junction structure may be applied to broader range of applications.

In view of the above, the present invention proposes a semiconductor PN junction structure and a manufacturing method for enhancing the breakdown voltage of a semiconductor device, to overcome the drawback in the prior art and provide a broader range of applications.

### SUMMARY OF THE INVENTION

The objectives of the present invention are to provide a semiconductor PN junction structure and a manufacturing method.

To achieve the foregoing objectives, the present invention provides a semiconductor PN junction structure comprising: a semiconductor substrate; and a PN junction including a P-type region and an N-type region interfacing with each other in the semiconductor substrate, wherein from top view, the PN junction includes a staggered comb-teeth interface between the P-type region and N-type region.

The staggered comb-teeth interface may be any regularly or irregularly staggered shape, wherein from top view, the comb-teeth interface preferably includes one or more of the following shapes: rectangle-shape, wave-shape, jag-shape and arc-shape. Besides, an opposite conductive type island-shaped doped region may be provided in the P-type region or the N-type region.

In one embodiment, the PN junction has multiple layers of comb-teeth interfaces under a surface of the semiconductor substrate.

When a reverse bias voltage is exerted on the PN junction to form depletion regions around the multiple teeth, the depletion regions are preferably connected together to become one depletion region.

In another perspective of the present invention, it provides a method for manufacturing a semiconductor PN junction structure comprising: providing a semiconductor substrate; and implanting impurities to form a PN junction including a P-type region and an N-type region interfacing with each other in the semiconductor substrate, wherein from top view, the PN junction includes a staggered comb-teeth interface between the P-type region and N-type region.

The objectives, technical details, features, and effects of the present invention will be better understood with regard to the detailed description of the embodiments below, with reference to the drawings.

### BRIEF DESCRIPTION OF THE DRAWINGS

FIG. 1A illustrates, by top-view, a schematic diagram of a prior art semiconductor PN junction structure.

FIG. 1B illustrates, by cross-section view, a schematic diagram of the prior art semiconductor PN junction structure.

FIG. 1C illustrates a depletion region formed in the prior art semiconductor PN junction structure.

FIG. 1D shows the strength and distribution of the electric field of the prior art semiconductor PN junction structure.

FIG. 2A shows, by top-view, a first embodiment of the semiconductor PN junction according to the present invention.

FIG. 2B shows the electric field of the semiconductor PN junction of the first embodiment according to the present invention.

FIG. 2C illustrates a comparison between the present invention and the prior art with respect to the strength and width of the electric field of the depletion region.

FIG. 3 shows, by top-view, another embodiment of the semiconductor PN junction according to the present invention.

FIG. 4 shows, by top-view, yet another embodiment of the semiconductor PN junction according to the present invention.

FIG. 5 shows, by top-view, a further other embodiment of the semiconductor PN junction according to the present invention.

FIG. 6 shows, by top-view, a still other embodiment of the semiconductor PN junction according to the present invention.

FIGS. 7A and 7B show another embodiment of the present invention.

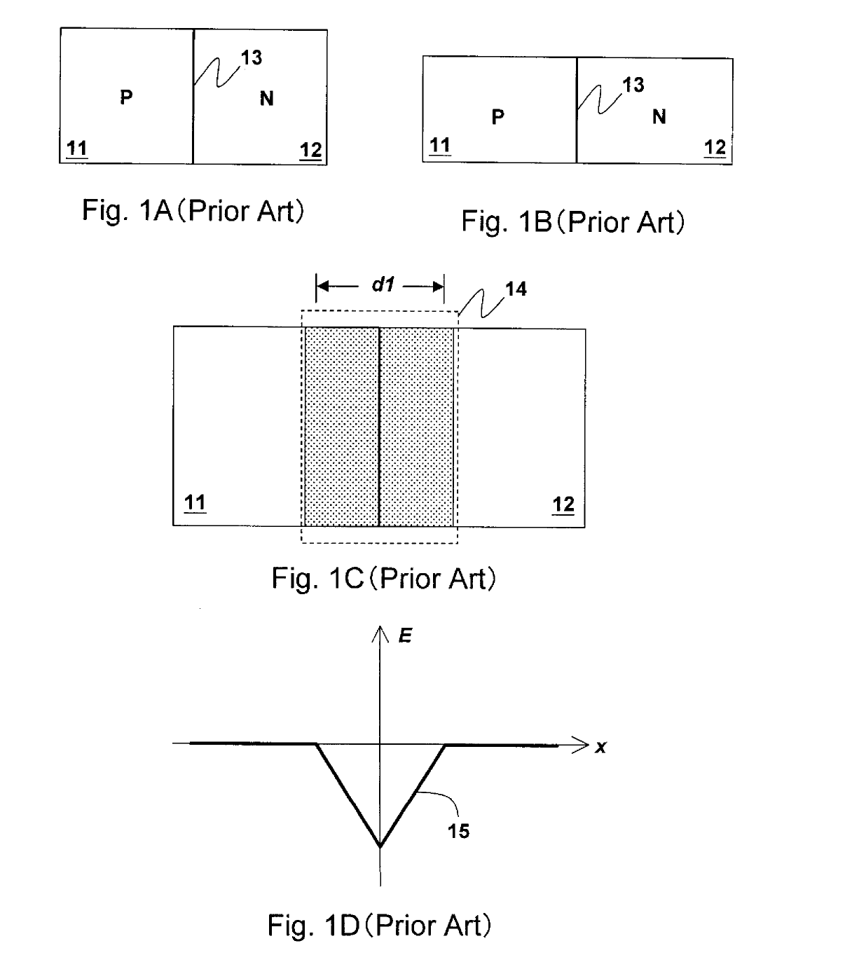

### DESCRIPTION OF THE PREFERRED EMBODIMENTS

The drawings as referred to throughout the description of the present invention are for illustration only, to show the interrelations between the regions, but not drawn according to actual scale.

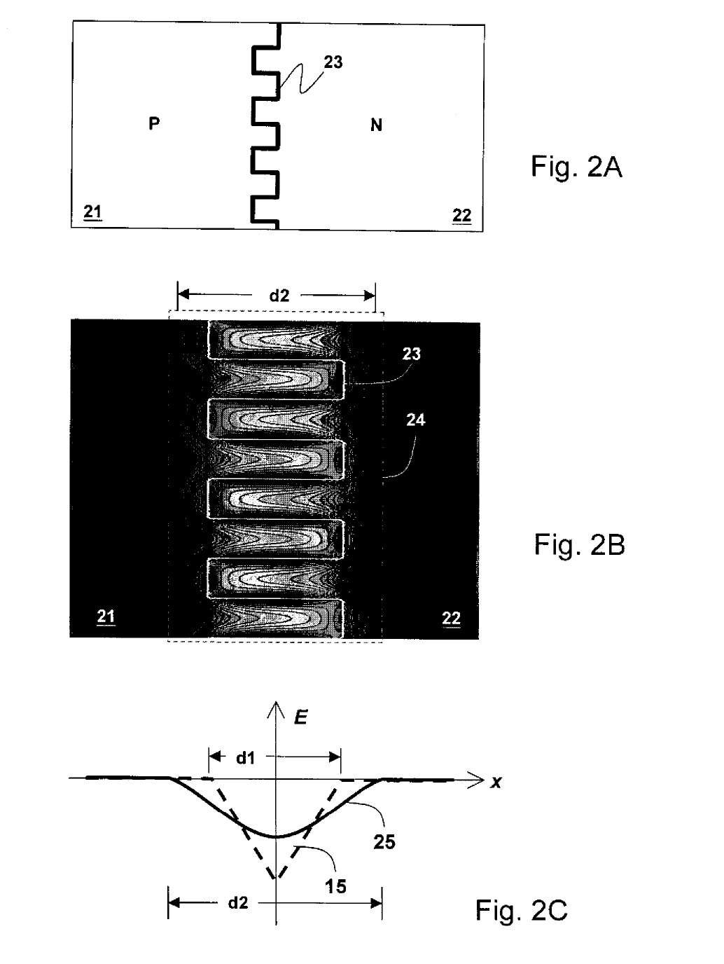

FIGS. 2A-2C show the first embodiment of the present invention, wherein FIG. 2A shows, by top view, a semiconductor PN junction formed by implanting impurities into a semiconductor substrate. As shown in FIG. 2A, a semiconductor P-type region 21 and an N-type region 22 interface with each other to form a PN junction 23, wherein from top view, the PN junction 23 includes a staggered comb-teeth interface between the P-type region 21 and N-type region 22. FIG. 2B shows the electric field of the PN junction 23, wherein because the PN junction 23 includes a staggered comb-teeth interface, depletion regions are formed along the interface, which turn left and right as the interface goes left and right, and if a spacing between the comb-teeth is not too large, the depletion regions around the comb-teeth are connected together to become one depletion region as the depletion region 24 shown in FIG. 2B. When no bias voltage, or a reverse bias voltage is exerted on the PN junction 23, the width of the depletion region 24 is d2.

FIG. 2C illustrates a comparison between the present invention and the prior art, wherein the bold line 25 indicates the strength and distribution of the electric field of the PN junction according to the present invention, while the dotted line 15 indicates the strength and distribution of the electric field of the PN junction according to the prior art. It can be seen from FIG. 2C that the present invention is superior to the prior art, because when the same reverse bias voltage is exerted on the PN junction 23, the width of the voltage-withstanding region, that is, the depletion region 24, is extended to d2 which is wider than the width d1 of the depletion region 14 in the prior art, and the electric field in the depletion region 24 is weaker than that in the depletion region 14 of the prior art. That is, when the same reverse bias voltage is exerted, the embodiment according to the present invention provides a weaker electric field and a wider depletion region, this means that the present invention can withstand a higher reverse bias voltage than that in the prior art, so that a semiconductor device having a PN junction of the present invention can be applied to a broader range of applications.

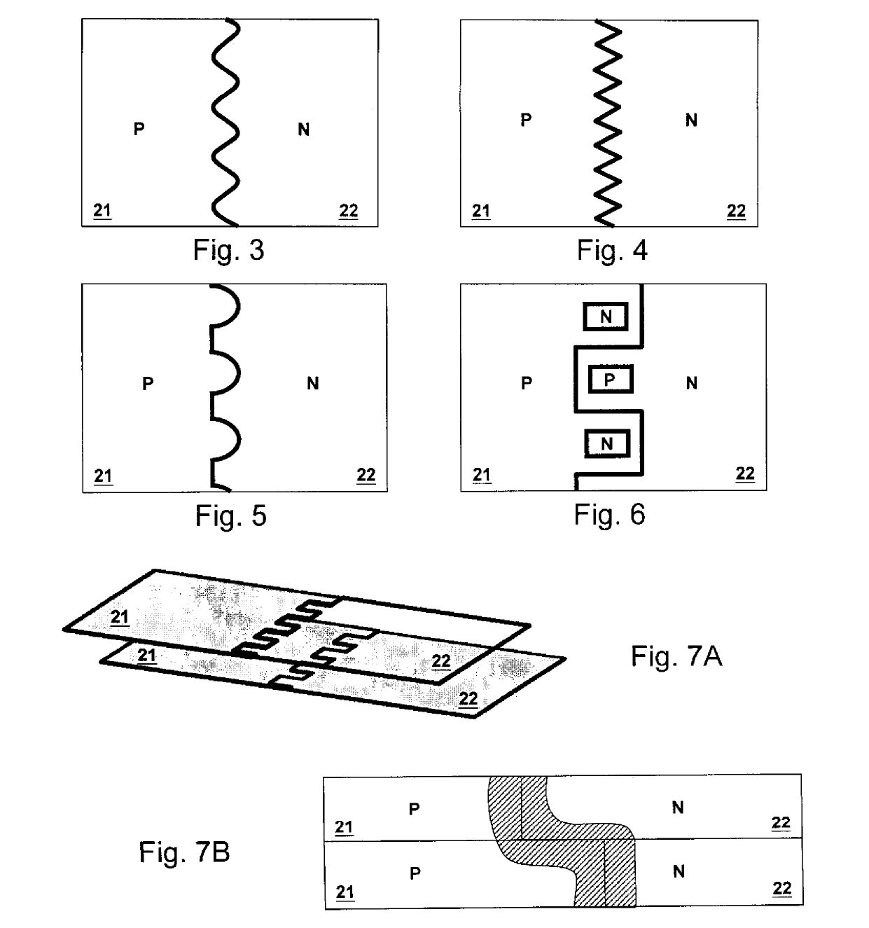

Next, FIGS. 3-6 show, by way of example, different shapes and distributions to embody the present invention. FIGS. 3-6 respectively show, by top view, four other PN junction of embodiments according to the present invention. Besides the rectangle-shaped comb-teeth interface shown in FIG. 2A, the semiconductor PN junction may include, for example but not limited to, a wave-shaped, jag-shaped and arc-shaped interface shown in FIGS. 3-5, respectively. And as FIG. 6 shows, an opposite conductive type doped region may be provided in the P-type region 21 and/or the N-type region 22 by implanting different conductive types of impurities. In fact, the “staggered comb-teeth interface” can be any regularly or irregularly staggered shape as long as the non-straight interface can broaden the depletion region and reduce the electric field.

FIGS. 7A and 7B show another embodiment of the present invention. As FIG. 7A shows, the staggered comb-teeth interface should not be limited to a single-layer structure, but also can include multiple layers of staggered comb-teeth interfaces under the surface of the semiconductor substrate. Furthermore, the different layers of comb-teeth interfaces need not be aligned with one another, but can be shifted from one other. FIG. 7B shows the cross-section of the PN junction according to this embodiment, wherein when the PN junctions of an upper layer and a lower layer are shifted from one the other, a vertical PN junction is formed. A depletion region is formed as the shaded region shown in the figure. According to one embodiment of the present invention, the depletion regions which are shifted from one another vertically is preferably connected together to become one depletion region so that the electric field is reduced and the breakdown voltage is increased.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention. For example, other manufacturing process steps or structures which do not affect the characteristics of the devices, such as a deep-well region, etc. As another example, the semiconductor substrate may be P-type or N-type, and in this case, it is not absolutely necessary for the PN junction to be formed by implanting two different conductive type impurities; in some cases, the PN junction may be formed just by implanting the impurities opposite to the conductive type of the semiconductor substrate. Thus, the present invention should cover all such and other modifications and variations, which should be interpreted to fall within the scope of the following claims and their equivalents.

What is claimed is:

1. A semiconductor PN junction structure comprising:
a semiconductor substrate; and
a PN junction including a P-type region and an N-type region interfacing with each other in the semiconductor substrate,
wherein from top view, the PN junction includes a staggered comb-teeth interface between the P-type region and N-type region.

2. The semiconductor PN junction structure of claim 1, wherein from top view, the comb-teeth interface includes one or more of the following shapes: rectangle-shape, wave-shape, jag-shape and arc-shape.

3. The semiconductor PN junction structure of claim 1, wherein an opposite conductive type island-shaped doped region is provided in the P-type region or the N-type region.

4. The semiconductor PN junction structure of claim 1, wherein the PN junction has multiple layers of comb-teeth interfaces under a surface of the semiconductor substrate.

5. The semiconductor PN junction structure of claim 1, wherein the comb-teeth interface includes multiple teeth, and when a reverse bias voltage is exerted on the PN junction to form depletion regions around the multiple teeth, the depletion regions are connected together to become one depletion region.

6. A method for manufacturing a semiconductor PN junction structure comprising:
providing a semiconductor substrate; and
implanting impurities to form a PN junction including a P-type region and an N-type region interfacing with each other in the semiconductor substrate,
wherein from top view, the PN junction includes a staggered comb-teeth interface between the P-type region and N-type region.

7. The method of claim 6, wherein the comb-teeth interface includes one or more of the following shapes: rectangle-shape, wave-shape, jag-shape and arc-shape.

8. The method of claim 6, wherein an opposite conductive type island-shaped doped region is provided in the P-type region or the N-type region.

9. The method of claim 6, wherein the PN junction has multiple layers of comb-teeth interfaces under a surface of the semiconductor substrate.

10. The method of claim 6, wherein the comb-teeth interface includes multiple teeth, and when a reverse bias voltage is exerted on the PN junction to form depletion regions around the multiple teeth, the depletion regions are connected together to become one depletion region.
